(19) United States
(12) Patent Application Publication
(10) Pub. No.: US 2001/0045848 A1
(43) Pub. Date: Nov. 29, 2001

(54) POWER-UP STABLE SIGNAL DETECTION CIRCUIT

(76) Inventor: MICHAEL C. STEPHENS JR., SAN JOSE, CA (US)

Correspondence Address: Jiawei Huang, 1340 Reynolds Avenue, Suite 114, Irvine, CA, 92614, US

(21) Appl. No.: 09/128,576

(22) Filed: Aug. 4, 1998

(51) Int. Cl. H03L 7/00

(52) U.S. Cl. 327/143

(57) ABSTRACT

A circuit for detecting when a derivative signal has reached its operating level during power-up of an integrated circuit includes a reset circuit, a latch circuit and a node monitoring circuit. The reset circuit, latch circuit and node monitoring circuit are all connected at a node. When power-up starts, the reset circuit causes the level at the node to be driven to an initial level corresponding to the level provided by an external power source. In response to this initial level at the node, the latch circuit generates an output signal with a level indicating that the derivative signal has not yet reached its operating level. The node monitoring circuit monitors the level of the derivative signal. When the level of the derivative signal reaches its operating level, the node monitoring circuit causes the level at the node to change so as to cause the latch circuit to generate the output signal with a level that indicates that the derivative signal has reached its operating level. The output signal is used to activate circuitry that uses the derivative signal as soon as the derivative signal has reached its operating level.

### FIELD OF THE INVENTION

The present invention is related to integrated circuit devices and, more particularly, to power-up detection circuits for use in integrated circuit devices.

### BACKGROUND INFORMATION

Integrated circuits (i.e., chips) typically receive at least one supply voltage from an external power source. When the voltage is first applied to a chip, the chip undergoes “power-up” as the voltage on the chip's supply buses stabilize at the supply voltage level. The duration of power-up generally depends on several factors, including the capacitive loading of the supply buses, the current being drawn by devices in the chip during power up, the ramp rate of the external supply, and the maximum current that the external supply can output.

In addition, some chips include circuits that generate a DC signal from the external supply voltage (referred to herein as a derivative signal). Derivative signals typically follow and arrive at their stable level once the external supply voltage upon which they are dependent reaches its typical operating level. For example, a derivative signal may be a reference voltage generated by an on-chip voltage generator circuit from the external VDD supply voltage.

FIG. 1 is a timing diagram illustrative of a power-up sequence for an exemplary integrated circuit device having a DC signal that is derived from the external VDD supply voltage. In this example, the DC signal is a reference voltage VREF. Waveform 10 represents the level of the external VDD supply voltage during power-up. Typically, the voltage level of external supply voltage VDD increases from zero to the operating level over a relatively short time, indicated as time t_{VDD} in FIG. 1. In this example, the external VDD supply voltage is 3.3 volts.

Waveformn 12 represents the level of the derivative signal, reference voltage VREF. Because reference voltage VREF is derivative, the level of reference voltage VREF reaches the operating level some time after the external supply voltage reaches its operating level, indicated as time t_{VREF} in FIG. 1. In this example, reference voltage VREF is 1.5 volts. In some chips, if circuits use voltage VREF before it is stable, the circuits may enter an improper state. In extreme cases, the chip may not be able to leave an improper state when voltage VREF stabilizes, thereby preventing the chip from operating properly.

Alternatively, circuits that use reference voltage VREF can be disabled until the reference voltage VREF is stable. However, time t_{VREF} cannot be precisely determined because the ramp-up of reference voltage VREF depends on several factors such as the loading of the VREF bus (not shown), the ramp rate of external supply voltage VDD, the temperature, etc. Thus, these conventional systems generally delay the enabling of these circuits from the time that external supply voltage VDD is provided in an effort to ensure that reference voltage VREF is stable before the circuitry is enabled. Because the delay is generally selected to be longer that the worst case ramp-up of reference voltage VREF, this delay, in effect, adds a buffer time Δt to the nominal value of time t_{VREF} before enabling circuits that use reference voltage VREF. This is indicated as time t_{VREF}+Δt in FIG. 1.

This conventional delay technique helps to ensure that reference voltage VREF is stable under the expected worst-case conditions when the circuits that use reference voltage VREF are enabled. Of course, when the conditions are not worst-case, the buffer time Δt adds unnecessary delay to the power-up sequence. On the other hand, if the ramp-up of reference voltage VREF for some reason becomes longer than the selected delay, the circuits that use reference voltage VREF may operate improperly, with the attendant problems described above. Accordingly, there is a need for a method or structure that ensures that derivative DC signals are stable even when the ramp-up of the derivative signal changes and without adding extra delay to the power-up sequence.

### SUMMARY

In accordance with the present invention, a circuit is provided for detecting when a derivative signal has reached its operating level during power-up of an integrated circuit. In one aspect of the present invention, the detection circuit includes a reset circuit, a latch circuit and a node monitoring circuit. The reset circuit, latch circuit and node monitoring circuit are all connected at a first node.

Power-up begins when receives an external power source connected to the integrated circuit is activated. When the power-up sequence starts, the reset circuit causes the level at the first node to be driven to an initial level corresponding to the level provided by the external power source. In response to this initial level at the first node, the latch circuit generates an output signal with a level indicating that the derivative signal has not yet reached its operating level. The node monitoring circuit monitors the level of the derivative signal. When the level of the derivative signal reaches its operating level, the node monitoring circuit causes the level at the first node to change so as to cause the latch circuit to generate the output signal with a level that indicates that the derivative signal has reached its operating level. The output signal is advantageously used to activate or enable circuitry that uses the derivative signal as soon as the derivative signal has reached its operating level. This aspect of the invention allows the duration of the power-up sequence to be advantageously reduced in comparison to the aforementioned conventional systems that use an extra delay to ensure that the derivative signal is stable before activating circuitry that use the derivative signal. In addition, unlike these conventional systems, improper usage of the derivative signal is avoided if the ramp-up of the derivative signal happens to exceed the extra delay.

In one particular embodiment: the reset circuit is implemented with a capacitor connected between the node and the VDD supply bus; the monitoring circuit is implemented with an N-channel field effect transistor having its gate connected to receive the derivative signal and its source/drain regions connected to the ground bus and the node; and the latch circuit is implemented with two latch-connected inverters. The N-channel transistor and the latch-connected inverters are sized so that the N-channel transistor will pull down the voltage at the node when the level of the derivative signal is at its operating level. The latch circuit also includes an output buffer implemented with two cascaded inverters.

### BRIEF DESCRIPTION OF THE DRAWINGS

The foregoing aspects and many of the attendant advantages of this invention will become more readily appreciated by reference to the following detailed description, when taken in conjunction with the accompanying drawings listed below.

FIG. 1 is a timing diagram illustrative of a power-up sequence for an exemplary integrated circuit device having a DC signal that is derived from an external supply voltage.

FIG. 2 is a block diagram illustrative of a power-up stable signal detection circuit, according to one embodiment of the present invention.

FIG. 3 is a schematic diagram illustrative of a power-up stable signal detection circuit, according to one embodiment of the present invention.

FIG. 4 is a timing diagram illustrative of a power-up sequence for an exemplary integrated circuit having a power-up stable signal detection circuit, according to one embodiment of the present invention.

### DETAILED DESCRIPTION

FIG. 2 is a block diagram illustrative of a power-up stable signal detection circuit 20, according to one embodiment of the present invention. Detection circuit 20 includes a reset circuit 22, a latch circuit 24 and a node monitoring circuit. In this embodiment, the node monitoring circuit is implemented using a pull-down circuit 26. Reset circuit 20 is connected to a node N1 and a VDD bus that carries the external supply voltage VDD. Latch circuit 24 has an input lead connected to node N1 and outputs a signal REFUP as a function of the logic level of the voltage at node N1. Pull-down circuit 26 has a lead connected to receive reference voltage VREF, a lead connected to a ground bus, and a lead connected to node N1.

Circuit 20 operates as follows. During power-up, pull-down circuit 26 monitors the level of reference voltage VREF. In this embodiment, pull-down circuit 26 is configured to be activated (i.e., to pull-down the voltage at node N1) about when the level of reference voltage VREF reaches the predetermined operational level of reference voltage VREF. If the level of voltage VREF is below this activation level, pull-down circuit 26 provides a high impedance path between node N1 and the ground bus.

Reset circuit 22 is configured to cause the voltage level at node N1 to track the level of external supply voltage VDD at the start of power-up to properly reset latch circuit 24. Assuming that node N1 is initially at zero volts, at the onset of power-up, the voltage level at node N1 increases at about the same rate as external supply voltage VDD. In addition, once the voltage level at node N1 reaches a threshold level, latching circuit 24 assists reset circuit 22 to increase and maintain the voltage level at node N1 at the level of external supply voltage VDD. In response to the relatively high voltage level at node N1, latch circuit 24 also causes signal REFUP to be deasserted.

As the voltage level of external supply voltage VDD increases, the voltage level of the derivative signal (i.e., reference voltage VREF in this embodiment) will eventually reach the desired operational level. At this point, pull-down circuit 26 pulls down the voltage at node N1 (VN1) to a logic low level. Pull-down circuit 26 is sized so as to overcome reset circuit 22 and latch circuit 24 in maintaining a logic high voltage level at node N1. In response to the logic low voltage level at node N1, latch circuit 24 asserts signal REFUP. Because signal REFUP is asserted directly from monitoring the level of reference voltage VREF, no extra delay is needed in activating any circuits that use reference voltage VREF, thereby advantageously reducing the duration of the power-up sequence. In addition, unlike the aforementioned conventional systems that use an extra added delay, this direct monitoring avoids enabling these circuits when the ramp-up of reference voltage VREF happens to take longer than accounted for by the added extra delay.

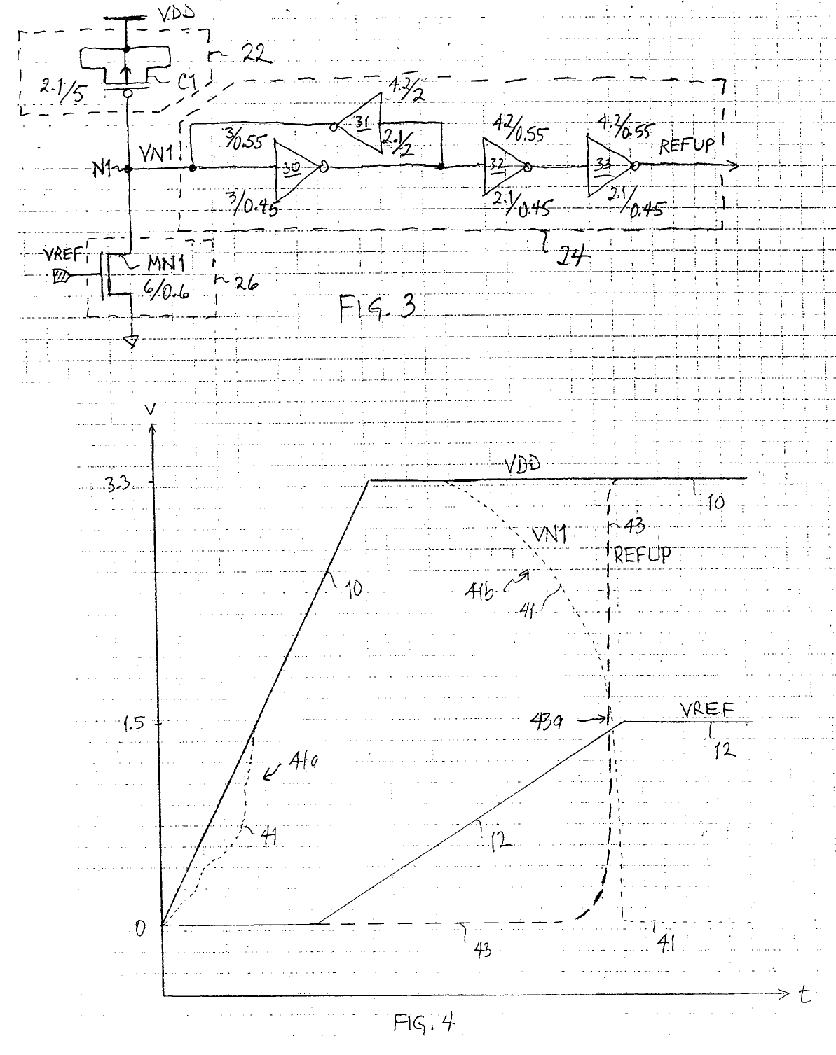

FIG. 3 is a schematic diagram illustrative of power-up stable signal detection circuit 20 (FIG. 2), according to one embodiment of the present invention. In this embodiment, reset circuit 22 is implemented with a capacitor C1 formed with a P-channel transistor. The gate of the P-channel transistor is connected to node N1 whereas the source and drain regions of the P-channel transistor are connected to the VDD supply bus. In this embodiment, capacitor C1 has a capacitance ranging from about 10 fF to 100 fF.

Latch circuit 24 is an inverting latch circuit implemented with four conventional CMOS inverters 30-33. Inverter 30 is slightly smaller than inverters 31-33, with its input lead connected to node N1, which helps to reduce the capacitive load at node N1. Inverter 31 has its input and output leads connected to the output and input leads of inverter 30, respectively. The pull-up and pull-down devices of inverter 31 have relatively small width-to-length (W/L) ratios. Consequently, the pull-up and pull-down strengths of inverter 31 are relatively small. Inverters 32 and 33 are connected in cascade so as to buffer the output signal generated by inverter 30 to serve as signal REFUP.

Pull-down circuit 26 is implemented with an N-channel transistor MN1, having its gate connected to receive reference voltage VREF, its source connected to the ground bus, and its drain connected to node N1. The size of N-channel transistor MN1 is predetermined so as to overcome the pull-up device of inverter 31 in latch circuit 24 when the level of reference voltage VREF is equal to the operating level of reference voltage VREF. The operation of this embodiment is described in more detail below in conjunction with FIG. 4.

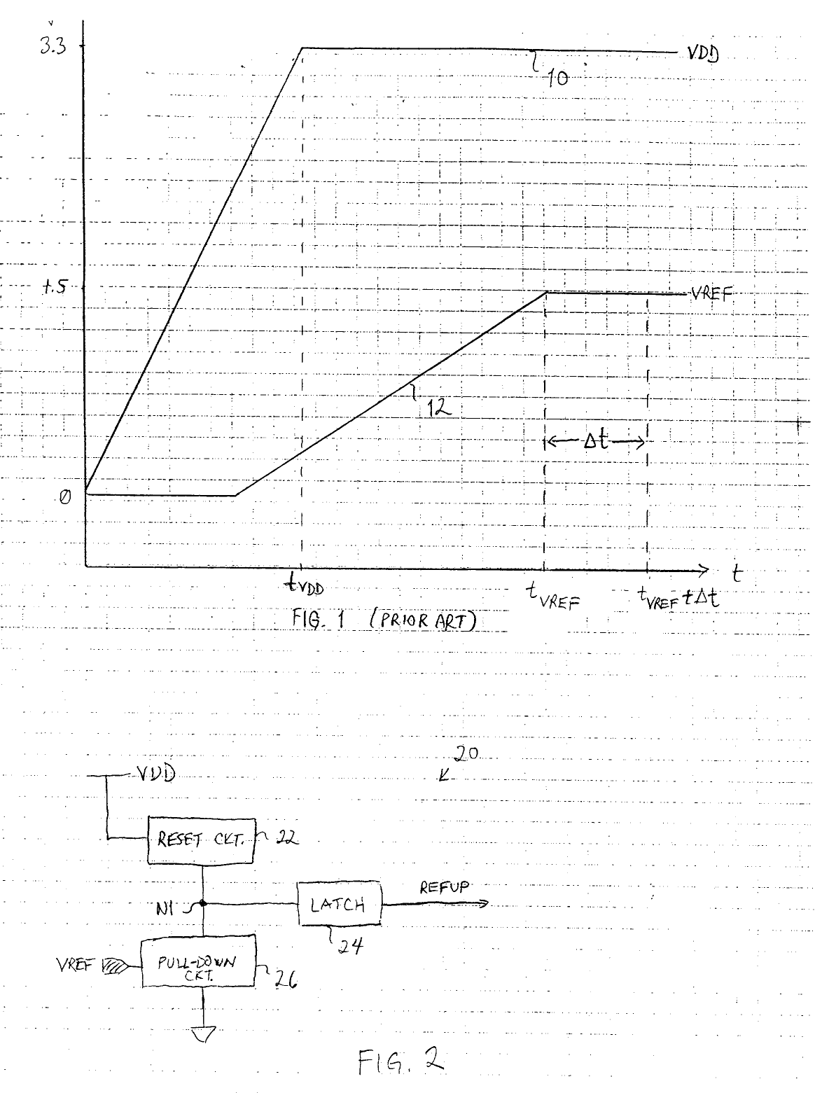

FIG. 4 is a timing diagram illustrative of a power-up sequence for the embodiment of circuit 20 (FIG. 3). Waveforms 10 and 12 are essentially the same as described previously in conjunction with FIG. 1. However, FIG. 4 includes waveforms 41 and 43 that represent voltage VN1 (i.e., the level at node N1) and signal REFUP, respectively. Referring to FIGS. 3 and 4, as the level of external supply voltage VDD increases to its operating level of 3.3 volts during power-up, capacitor C1 causes the level of voltage VN1 to roughly track the level of external supply voltage VDD. As indicated by the initial portion 41a of waveform 41, the level of voltage VN1 can be slightly irregular and lag the level of external supply voltage VDD. Then as the level of external supply voltage VDD increases to about 1.5 volts (i.e., the logic high CMOS level), inverter 31 helps capacitor C1 to pull up and maintain the voltage level at node N1 to be essentially equal to the level of external supply voltage VDD.

As indicated by waveform 43, the level of signal REFUP is initially at a logic low level. Waveform 43 remains at a logic low level as the level of reference voltage VREF (i.e., represented by waveform 12) begins to increase and is below the operating level of about 1.5 volts. However, as the level of reference voltage VREF increases to about one-half volt, N-channel transistor MN1 begins to turn on, thereby pulling down the level of voltage VN1 slightly. As the level of reference voltage VREF continues to increase, N-channel transistor MN1 becomes more conductive, which causes the level of voltage VN1 to continue to decrease, as indicated by portion 41b of waveform 41. However, N-channel transistor MN1 is sized so that, ideally, the level of voltage VN1 does not reach the trip point of inverter 30 until the gate voltage (i.e., reference voltage VREF) of N-channel transistor MN1 reaches the operating level of 1.5 volts. In light of this disclosure, those skilled in the art of integrated circuits can use commercially available modeling tools to determine a suitable size for N-channel transistor MN1 and the devices used to implement inverter 30. Then when the level of reference voltage VREF reaches 1.5 volts, N-channel transistor MN1 pulls down the level of voltage VN1 to a level that causes inverter 30 to output a logic low level, which is propagated through inverters 32 and 33 to serve as signal REFUP. This transition of signal REFUP is indicated by portion 43a of waveform 43.

Although the above embodiment is for use with a voltage reference signal derived from external supply voltage VDD, other embodiments can be implemented for use with other analog derivative signals. For example, the analog derivative signal may be derived from an on-chip generated signal, or the analog derivative signal may represent the analog output signal of a sensor. In addition, as is appreciated by those skilled in the art, the sizes and ratios of the pull-up and pull-down devices in inverter 30 and pull-down circuit 26 can be changed to detect voltage levels other than the 1.5 volts of the above embodiment.

The embodiments of the power-up stable signal detection circuit described above are illustrative of the principles of the present invention and are not intended to limit the invention to the particular embodiments described. For example, in light of this disclosure, those skilled in the art of integrated circuits can implement other embodiments of the latch circuit that are different from the latch circuit described, without undue experimentation. As another example, an embodiment for use with a negative reference level may be implemented by connecting capacitor C1 to the ground bus and using a pull-up circuit instead of pull-down circuit 26. Still further, other embodiments may use a bipolar transistor or a transistor device of other transistor technology instead of transistor MN1. Accordingly, while the preferred embodiment of the invention has been illustrated and described, it will be appreciated that various changes can be made therein without departing from the spirit and scope of the invention.

I claim:

1. A method of detecting a level of a first analog signal derived from a second analog signal during power-up of an integrated circuit, the first analog signal having an operating level, the method comprising:
generating an output signal having a logic level as a function of a level at a first node by monitoring the level at the first node and generating a digital signal as a logical function of the monitored level;
resetting the level at the first node to a first logic level upon power-up of the integrated circuit by electromagnetically coupling the second analog signal to the first node;
monitoring a level of the first analog signal by changing a conductivity of a path as a function of the level of the first analog signal; and
changing the level at the first node to a second logic level when the level of the first analog signal reaches the operating level by transferring charge between the first node and a supply bus through the path as a function of the level of the first analog signal.

2. The method of claim 1 wherein a transistor is used to monitor a voltage level at the first node, the transistor having a first lead coupled to receive the first signal and having a second lead coupled to the first node.

3. The method of claim 2 wherein the supply bus is a voltage supply bus and the transistor provides the path between the first node and the supply bus when the level of the first signal is about equal to the operating level.

4. The method of claim 3 wherein the transistor is an N-channel field effect transistor and the supply bus is a ground bus.

5. The method of claim 2 wherein a capacitor circuit is used to reset the voltage level at the first node upon power-up.

6. The method of claim 5 wherein the capacitor circuit is coupled to the first node and to a conductive line carrying the second analog signal.

7. The method of claim 2 wherein a latch circuit having an input lead coupled to the first node is used to generate the output signal.

8. The method of claim 7 wherein the latch circuit has pull-up and pulldown devices coupled to the first node, the transistor and the pull-up and pull-down devices having sizes that are predetermined to cause the latch circuit to transition when the level of the first signal is essentially equal to the operating level.

9. A circuit of detecting a level of a first analog signal derived from a second analog signal during power-up of an integrated circuit, the first analog signal having an operating level, the circuit comprising:
means for generating an output signal having a logic level as a function of a level at a first node;
means for resetting the level at the first node to a first logic level upon power-up of the integrated circuit; and
means for changing the level at the first node to a second logic level when the level of the first analog signal reaches the operating level.

10. The circuit of claim 9 wherein the means for changing includes a transistor having a first lead coupled to receive the first signal and having a second lead coupled to the first node.

11. The circuit of claim 10 wherein the transistor provides a conductive path between the first node and a voltage supply bus when the level of the first signal is about equal to the operating level.

12. The circuit of claim 11 wherein the transistor is an N-channel field effect transistor and wherein the voltage supply bus is a ground bus.

13. The circuit of claim 10 wherein the means for resetting includes a capacitor coupled to the first node and coupled to a conductive line carrying the second analog signal.

14. The circuit of claim 13 wherein the capacitor circuit is implemented with a P-channel field effect transistor.

15. The circuit of claim 10 wherein the means for generating includes a latch circuit having an input lead coupled to the first node.

16. The circuit of claim 15 wherein the latch circuit has a pull-up device and a pull-down device coupled to the first node, the transistor and the pull-up and pull-down devices having sizes that are predetermined to cause the latch circuit to transition when the level of the first signal is essentially equal to the operating level.

17. A circuit of detecting a level of a first analog signal derived from a second analog signal during power-up of an integrated circuit, the first analog signal having an operating level, the second analog signal being conducted by a conductive line, the circuit comprising:
a latch circuit having an input lead coupled to a first node;
a capacitor coupled to the conductive line and the first node; and
a transistor coupled to receive the first analog signal and to the first node, the transistor configured to change a level at the first node to a second logic level when the voltage level of the first analog signal reaches the operating level.

18. The circuit of claim 17 wherein the transistor has a first lead coupled to receive the first signal and has a second lead coupled to the first node.

19. The circuit of claim 18 wherein the transistor forms a conductive path between the first node and a voltage supply bus when the level of the first signal is about equal to the operating level.

20. The circuit of claim 19 wherein the transistor is an N-channel field effect transistor and wherein the voltage supply bus is a ground bus.

21. The circuit of claim 17 wherein the capacitor is implemented with a P-channel field effect transistor.

22. The circuit of claim 17 wherein the latch circuit comprises a first inverter and a second inverter.

23. The circuit of claim 22 wherein the first inverter of the latch circuit has a pull-up device and a pull-down device coupled to the input lead of the latch circuit, the transistor and the pull-up and pull-down devices having sizes that are predetermined to cause the first inverter to transition its output signal when the level of the first signal is essentially equal to the operating level.
